(19) United States
(12) Patent Application Publication
(10) Pub. No.: US 2006/0130890 A1
(43) Pub. Date: Jun. 22, 2006

(54) Heterojunction photovoltaic cell

(75) Inventors: Thomas Hantschel, Menlo Park, CA (US); Karl A. Littau, Palo Alto, CA (US); Scott A. Elrod, La Honda, CA (US)

Correspondence Address: Jude A. Fry;FAY, SHARPE, FAGAN, MINNICH & McKEE, LLP, SEVENTH FLOOR, 1100 SUPERIOR AVENUE, CLEVELAND, OH, 44114-2579, US

(73) Assignee: PALO ALTO RESEARCH CENTER INCORPORATED.

(21) Appl. No.: 11/017,380

(22) Filed: Dec. 20, 2004

(51) Int. Cl. H01L 31/00

(52) U.S. Cl. 136/252; 136/265

(57) ABSTRACT

In accordance with one aspect of the present disclosure, a solar photovoltaic device is disclosed. The semiconductor material of the solar photovoltaic device is a heterostructure of two different binary compounds of a pair of immiscible metals. The two different binary compounds have a conduction band edge offset of greater than about 0.4 eV. The binary compound acting as the optical absorbing material of the solar photovoltaic device has a bandgap of about 1.0 eV to about 1.8 eV.

### BACKGROUND

The present disclosure relates to semiconductor devices, and more particularly, to solar photovoltaic cells.

A photovoltaic cell is a component in which light is converted directly into electric energy.

A heterojunction photovoltaic cell is one in which two dissimilar materials are used to generate the bias field and induce charge separation between generated electrons and holes.

A heterojunction photovoltaic cell comprises at least one light-absorbing layer and a charge transport layer, as well as two electrodes. If the converted light is sunlight, the photovoltaic cell is a solar cell.

For solar photovoltaic cells, one would ideally want to use low-cost, non-toxic and abundant source materials and process these materials at low temperature on inexpensive substrates. The mobilities of such materials are often poor. For example, copper oxide (CuO) has a nearly ideal band gap (1.6 eV) for a solar photovoltaic device, but has a low mobility (<10⁻¹ cm²/V-sec) when oxidized at about 400-500° C.

Heterojunctions of dissimilar semiconductors are often used to create solar cells. The fabrication process for junctions of dissimilar materials is usually complex, and the manufacturing cost is high.

In this regard, state-of-the-art heterojunction solar cells between dissimilar inorganic semiconductors require very careful engineering in order to avoid carrier recombination at interface states. Moreover, these cells are problematic in that there is mixing of the semiconductors at the junctions of the cells. Often the devices are made using epitaxial techniques in order to insure the quality of the interface. Further, defects in the bulk must be minimized so that charges can propagate to their respective electrodes, which must be separated by at least the absorption length of incident photons.

Thus, the need exists for a photovoltaic cell having a heterojunction of dissimilar semiconductors, which is easily fabricated from low-cost, non-toxic, abundant source materials. The semiconductors are dissimilar inorganic semiconductors that reduce the likelihood of intermixing at the junction of the cell allow for electrons and holes to propagate to the electrodes of the photovoltaic cell.

The present disclosure contemplates a new and improved solar photovoltaic cell and method which overcomes the above-referenced problems and others.

### BRIEF DESCRIPTION

In accordance with one aspect of the present disclosure, a solar photovoltaic device is disclosed. The solar photovoltaic device includes a heterostructure of a charge transport material and an optical absorbing material. The charge transport material and the optical absorbing material are binary compounds of two immiscible metals. The optical absorbing material has a bandgap of about 1.0 eV to about 1.8 eV. The solar photovoltaic device also includes a first transparent electrode disposed on a top surface of the heterostructure, as well as a second electrode disposed on a bottom surface of the heterostructure.

In accordance with another aspect of the present disclosure, a semiconductor layer for a solar photovoltaic device is disclosed. The semiconductor layer is a heterojunction of a charge transport material and an optical absorbing material. Each of the charge transport material and the optical absorbing material is a different binary compound of two immiscible metals.

In accordance with yet another aspect of the present disclosure, a method for making a heterojunction of inorganic semiconductors for a solar photovoltaic device is disclosed. A layer of a first metal is deposited. A layer of a second metal is deposited. The first metal and second metal are immiscible metals. A compound of the first metal is formed in a depth of the first metal layer. A compound of the second metal is formed in a depth of the second metal layer so as to create a heterojunction between the compound of the first metal and the compound of the second metal.

In accordance with still another aspect of the present disclosure, a method for making a solar photovoltaic device is disclosed. A layer of a compound of a first metal is deposited on a first electrode. A layer of a compound of a second metal is deposited on the layer of the compound of the first metal. The first metal and the second metal are immiscible metals. A heterostructure is created between the compound of the first metal and the compound of the second metal. A second electrode is formed on the heterostructure.

### BRIEF DESCRIPTION OF THE DRAWINGS

The embodiments disclosed herein may take form in various components and arrangements of components, and in various steps and arrangements of steps. The drawings are only for purposes of illustrating embodiments and are not to be construed as limiting the embodiment.

FIG. 1 is a cross-sectional view of a solar photovoltaic cell according to an embodiment of the present disclosure;

FIG. 2 is a band gap diagram showing the unequilibrated components of a solar photovoltaic cell according to an embodiment of the present disclosure;

FIG. 3 is a band gap diagram showing the equilibrated components of a solar photovoltaic cell according to an embodiment of the present disclosure;

FIGS. 4a-4c is a flow chart showing the manufacturing of a solar photovoltaic cell according to an embodiment of the present disclosure; and

FIG. 5 is a cross-sectional view of a solar photovoltaic cell according to a second embodiment of the present disclosure.

### DETAILED DESCRIPTION

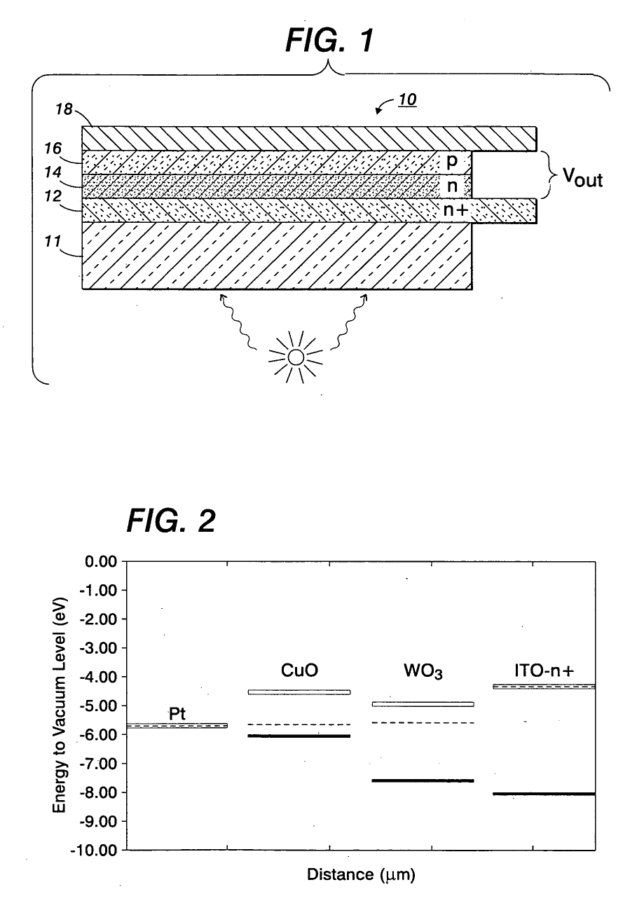

Referring now to FIG. 1, a photovoltaic cell 10 is illustrated. The photovoltaic cell 10 is a planar device and includes an electrically conductive support formed of an optically transparent substrate 11 and a transparent electrically conductive film 12.

The material used in the substrate 11 is not particularly limited and can be various kinds of transparent materials, and glass is preferably used.

The material used in the transparent electrically conductive film 12 is also not particularly limited, and it is preferred to use a transparent electrically conductive metallic oxide such as fluorinated tin oxide (SnO₂:F), antimony-doped tin oxide (SnO₂:Sb), indium tin oxide (ITO), aluminum-doped zinc oxide (AnO:Al) and gallium-doped zinc oxide (ZnO:Ga). The preferred materials for the transparent electroconductive film 12 are ITO or fluorinated tin oxide.

Examples of the method for forming the transparent electrically conductive film 12 on the substrate 11 include a vacuum vapor deposition method, a sputtering method, a CVD (Chemical Vapor Deposition) method using a component of the material, and a coating method by a sol-gel method. Preferably, the electrically conductive support is formed by sputter depositing ITO on a glass substrate, using process conditions well-known to those of ordinary skill in the art.

Disposed atop the transparent electrically conductive film 12 is a heterojunction of a charge transport material 14 and an optical absorbing material 16.

In order to create the heterojunction, compounds of a pair of immiscible metals are used, e.g., the oxide and sulfide of a pair of immiscible metals, or the oxide and phosphide of a pair of immiscible metals. By immiscible, it is meant that the solubility of one metal in the other is effectively zero up to the maximum processing temperature of the solar cell device. For detailed data on miscibility, see for example “Constitution of Binary Alloys”, by Hansen, M. and Anderko, K., McGraw Hill, New York (1958).

The term metal refers to, in the Periodic Table, elements 21-29 (scandium through copper), 39-47 (yttrium through silver), 57-79 (lanthanum through gold), all elements from 89 (actinium), in addition to aluminum, gallium, indium and tin. The metal is preferably a transition metal.

There are unique cases in which compounds of a pair of immiscible metals have the desired band gaps, band alignments and majority carrier type to create a heterojunction of dissimilar inorganic semiconductors which allows for charge separation and propagation of charges to external electrodes.

Given the proper choice of immiscible metals, a heterojunction is created using certain compounds of those metals. One of the compounds acts as an optically-excitable semiconductor (i.e., the optical absorbing material 16), while the second compound acts as a higher bandgap semiconductor used for charge transport (i.e., the charge transport material 14).

An ideal bandgap for solar absorption is in the range of about 1.0 eV to about 1.8 eV, and a conduction band edge offset for charge separation is greater than about 0.4 eV. One example of binary compounds of a pair of immiscible metals satisfying these constraints and suitable for use in the present disclosure is tungsten oxide (WO₃) and copper oxide (CuO). Specifically, tungsten oxide has a bandgap of approximately 2.7 eV. In addition, with proper doping the conduction band offset between tungsten oxide and copper oxide can be made greater than 0.4 eV.

Thus, WO₃ is an n-type semiconductor, while CuO is a p-type semiconductor. In this regard, their band alignments and band gaps are suitable for a solar cell device as demonstrated in FIG. 2. The n-type WO₃, having a large band gap of approximately 2.7 eV acts as the charge transport material 14 in the solar photovoltaic cell 10 of FIG. 1. The CuO, a p-type material with a band gap of approximately 1.65 eV, acts as the optical absorbing material 16 in the solar photovoltaic cell 10 of FIG. 1.

Although the present disclosure refers to the binary compounds with exact stoichiometries, it is not intended to be limited thereby. The referenced binary compounds include materials with approximate compositions as well as compositions within±30% of the as written ratio of elements.

The use of immiscible metals reduces the risk of intermixing at the junction, in order to maintain an abrupt junction suitable for maximum photovoltaic output. It will be appreciated that while the metals themselves may be immiscible, their compounds may in fact be soluble in one another. Further, there may exist more complex compounds of the two metals with other components. For a heterojunction between CuO and WO₃, one example of such a possible complex compound is WCuO₄. Still, the use of immiscible metals as the basis for the two halves of the heterojunctions reduces the likelihood of intermixing.

As understood by one of ordinary skill in the art, doping of the charge transport material 14 and/or the optical absorbing material 16 is used to create a conduction band edge difference or offset of greater than about 0.4 eV. For example, FIG. 2 corresponds to the unequilibrated components of a heterojunction comprising a transparent n+ITO, n-type WO₃, p-type CuO and a platinum back electrode. In this particular case, the doping of the WO₃ is assumed to place the Fermi level half way between the midpoint of the energy gap and the conduction band edge. Similarly, the CuO is assumed to have its Fermi level half way between the midpoint of its energy gap and the valence band edge. It will be appreciated by those skilled in the art that a wide variation in doping levels can generally be achieved through process conditions used for the material deposition, post-treatment steps like annealing and hydrogenation, and the intentional introduction of impurities.

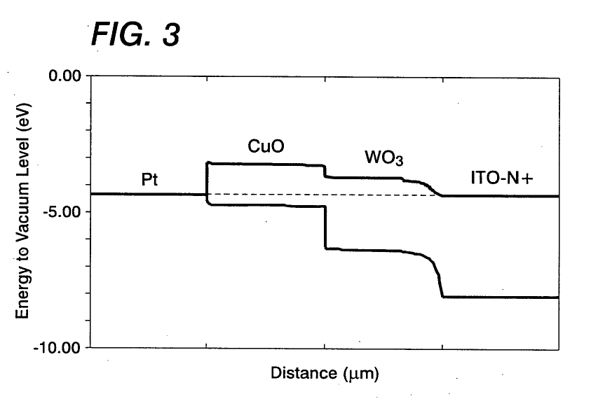

FIG. 3 shows the positions of the band edges once the materials have been brought into contact and the Fermi levels have equilibrated. For this particular assumption in doping levels, the difference in the conduction band edges between CuO and WO₃ is at the desired level of approximately 0.4 eV.

Other metals having binary compounds of a pair of immiscible metals may also be used in the present disclosure as would be understood by one of ordinary skill in the art. For example, binary phase diagrams like those disclosed by Hansen, M. and Anderko, K. in “Constitution of Binary Alloys” McGraw Hill, New York (1958) reveal that certain metal pairs are immiscible. For example, pairs of immiscible metals include but are not limited to the following: chromium and bismuth; manganese and tungsten; copper and tungsten; copper and tantalum; copper and molybdenum; zinc and molybdenum; tin and molybdenum; tin and tungsten; and, bismuth and tungsten.

Based on this list of suitable immiscible metal pairs, Table I is a list of suitable examples of binary compounds for use as the charge transport material 14 and optical absorbing material 16 for the photovoltaic device 10.

TABLE I

| Charge Transport | Optical Absorbing | Bandgap of Optical |
|---|---|---|
| Material 14 | Material 16 | Absorbing Material |
| ZnO | WS₂ | 1.13 |
| SnO₂ | WS₂ | 1.13 |
| WO₃ | SnS | 1.16 |
| WO₃ | Zn₄Sb₃ | 1.2 |
| ZnO | MoS₂ | 1.26 |
| SnO₂ | MoS₂ | 1.26 |
| Ta₂O₅ | Cu₂S | 1.3 |
| WO₃ | Cu₂S | 1.3 |
| WO₃ | Zn₃P₂ | 1.3 |
| WO₃ | ZnP₂ | 1.33 |
| Cr₂O₃ | Bi₂S₃ | 1.42 |
| WO₃ | Bi₂S₃ | 1.42 |
| Ta₂O₅ | CuO | 1.65 |
| WO₃ | CuO | 1.65 |

Inner diffusion of atoms is less problematic in the formed heterojunction of the photovoltaic cell 10. Because the metals are immiscible, there is no migration or diffusion of different metal atoms into the opposite side of the junction, thereby changing properties at the opposite junction. Although there is a possibility that the compounds of the metals will inter-mix, that possibility is greatly reduced by the use of a pair of immiscible metals.

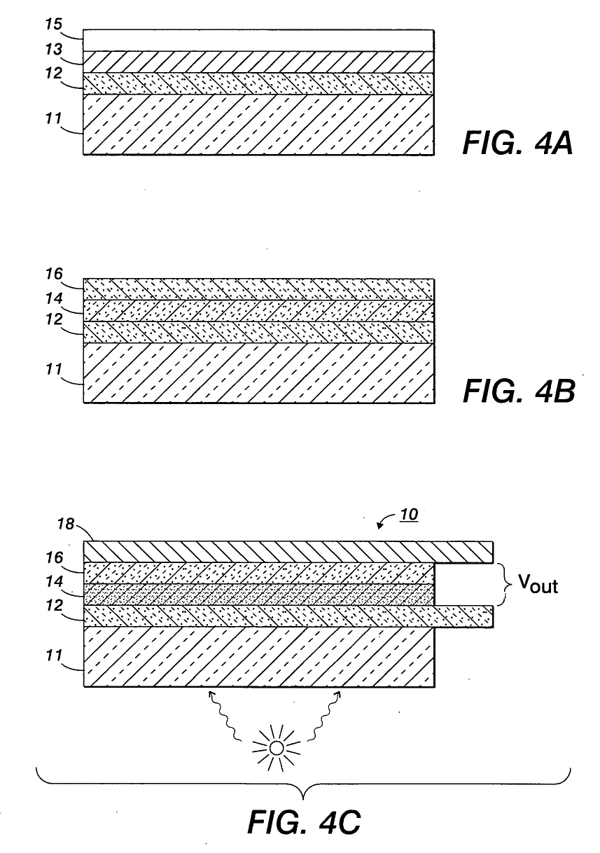

A representative process flow used to form the photovoltaic cell 10 is shown in FIGS. 4a-4c. As is illustrated in FIG. 4a, a transparent electrically conductive film 12 is sputter deposited on the glass substrate 11 in a manner understood by one of ordinary skill in the art using known process conditions.

A layer of tungsten metal 13 or any other suitable metal is then sputter deposited in vacuum on the formed electrically conductive support using processing conditions well-known to one of ordinary skill in the art. In addition, electroplating, CVD or evaporation could be used for forming the tungsten layer on the electrically conductive support.

A layer of copper metal 15 is deposited on the tungsten layer by sputter depositing in vacuum or any other known method, like electroplating, CVD or evaporation. The nominal thickness of the formed metal layers is about 10 nm to about 100 nm, preferably about 40 nm.

FIG. 4b illustrates the flow process for making the solar photovoltaic device 10 based on the oxidation of the immiscible metal films. The metal layer W—Cu stack is heated on a hot plate or in an oven in dry air or in oxygen at 300-500° C. for approximately 7-15 minutes to form an oxide of each of the metals. As understood by one of ordinary skill in the art, different oxidation times, oxidation environments and oxidation processes may be used in the oxidation process depending upon the desired results.

Another option for forming the WO₃/CuO heterojunction is to deposit WO₃ onto the formed electrically conductive support by directly depositing the compound through thermal evaporation using known processing conditions. The CuO compound is then deposited onto the WO₃ layer by thermal evaporation, also using known processing conditions. This method will typically lead to a lower stress film than the case of a metal thin-film that has been converted from the metal and can be used for the direct deposition of any of the metal compounds identified in Table I.

For example, this method can also be used for forming a heterojunction for a photovoltaic cell containing an optical absorbing material 16 that is not an oxide of the immiscible metal. With reference to Table I, thermal evaporation can be used for direct deposition of optical absorbing material 16 when the material is a sulfide or a phosphide of the immiscible metal.

Electrode 18 is deposited on the photovoltaic device 10 as indicated in FIG. 4c. Examples of electrode 18 include platinum, gold, silver, graphite and aluminum. Electrode 18 is deposited using well-known processes, including a vacuum evaporation method, a sputtering method or a CVD (Chemical Vapor Deposition) method.

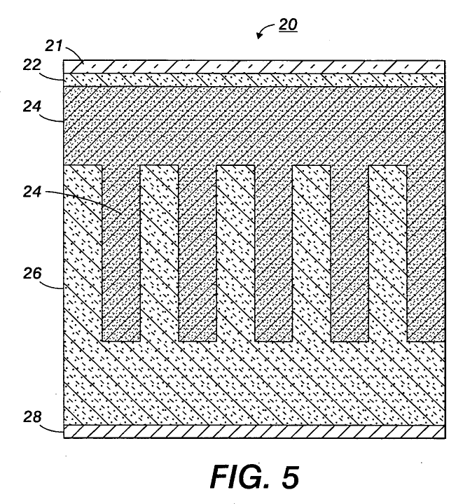

FIG. 5 differs from the embodiment of FIG. 1 in that a solar photovoltaic cell 20 includes a heterojunction of an interdigitated nanostructure of the charge transport material 24 and the optical absorbing material 26. This photovoltaic device is identified in our co-pending application of Elrod et al. (U.S. Ser. No. 10/957,946) entitled “Nanostructured Composite Photovoltaic Cell”, filed Oct. 4, 2004, the entire disclosure of which is incorporated herein by reference.

The solar photovoltaic cell 20 is fabricated by sputter depositing a layer of metal on the formed electrically conductive support including the optically transparent substrate 21 and transparent electrically conductive film 22.

In addition, electroplating, CVD or evaporation could be used for forming the layer of the metal on the electrically conductive support. The resultant metal layer has a thickness of about 100 nm to about 1000 nm.

The materials used for the optically transparent substrate 21 and transparent electrically conductive film 22 are identical to those identified for the substrate 11 and conductive film 12 in FIG. 1. The processes for forming the electrically conductive support are also identical to those referenced in connection with FIG. 1.

Anodic oxidation of the metal is used to form charge transport material 24 having discrete, hollow, substantially cylindrical pores. As disclosed by Gong et al. in an article entitled “Titanium Oxide Arrays Prepared by Anodic Oxidation,” J. Mater. Res., Vol. 16, No. 12, December 2001 or Masuda et al. in an article entitled “Highly Ordered Nanochannel-Array Architecture in Anodic Alumina,” Appl. Phys. Lett. 71 (19), 10 Nov. 1997, the disclosures of which are totally incorporated herein by reference, well-aligned metal oxide pore arrays are obtained through anodization in hydrogen fluoride (HF) solution using a well-known process.

The resulting pores are substantially straight, with a controllable pore diameter ranging from 10 to 100 nm; however, as understood by one of ordinary skill in the art, pore diameter is dependent on the desired characteristics of the optical absorber. Preferably, the diameter of the pore is shorter than the recombination distance in the optical absorbing material 26. The resulting pores also include a high aspect ratio (i.e., depth/width). For example, the aspect ratio of the pores ranges from about 3:1 to about 10:1.

With reference to WO₃ as the charge transport layer 24, high-purity (99.99%) tungsten is first sputter deposited on the electrically conductive film 22. Alternatively, the tungsten can be deposited by electroplating, CVD or evaporation using process conditions well-known to one of ordinary skill in the art.

The anodization is then conducted at room temperature (18° C.) with magnetic agitation. The aqueous solution contains from 0.5 to 3.5 wt. % HF. As is readily understood by one of ordinary skill in the art, different anodization temperatures, HF concentrations and chemical solutions can be used for the anodization step depending upon the desired outcome.

The anodizing voltages are preferably kept constant during the entire process but may be changed during the anodizing step. At increased voltages, discrete, hollow, substantially parallel and cylindrical pores appear in the tungsten oxide films. In particular, tungsten oxide pore arrays are obtained under anodizing voltages ranging from 10-40 volts as dependant on the HF concentration, with relatively higher voltages needed to achieve the tube-like structures in more dilute HF solutions.

If desired, a second oxidation step can be performed to ensure that the charge transport material 24 is fully oxidized, and as a wide bandgap semiconductor, transparent to most of the solar spectrum.

With reference to FIG. 5, the regular structure of the pores allows for optimization of the pitch with respect to the charge collection distance.

The pores in the charge transport material 24 of FIG. 5 are partially or wholly filled with a second metal that is immiscible with the first metal using processes well-known and understood to those of ordinary skill in the art prior to forming the heterojunction. Such processes for the filling of the pores of the charge transport material 24, include sputtering, electroplating, electroless plating, reflow CVD and evaporation.

For example, a transition metal such as copper can be easily sputtered and, using well-known plasma conditions, such as high-density plasma (HDP) sputtering with large substrate bias, the copper atoms can be directed normal to the incident surface. Moderate aspect ratios such as 2:1 or 3:1 or even higher can be filled using sputtering.

In HDP sputtering the argon working gas is excited into a high-density plasma, which is a plasma having an ionization density of at least 10″ cm⁻³ across the entire space the plasma fills except the plasma sheath. Typically, an HDP sputter reactor uses an RF power source connected to an inductive coil adjacent to the plasma region to generate the high-density plasma. The high argon density causes a significant fraction of sputtered atoms to be ionized. If the pedestal electrode supporting the device being sputter coated is negatively electrically biased, the ionized sputter particles are accelerated toward the device to form a directional beam that reaches deeply into the narrow holes.

Electrochemical deposition or electroplating is the standard production method for depositing copper into trenches and vias in the semiconductor industry and can be used for filling the pores of the charge transport material 24 with the optical absorbing material 26. High aspect ratio filling is accomplished as is well-known to those of skill in the art using additives to the electroplating bath such as accelerants (e.g., sulfur-containing compounds) and surfactants (e.g., nitrogen-containing compounds) to enhance growth at the bottom and suppress it near the top. As is well understood in the art, electroplating requires a continuous seed layer in order to supply the required voltage across the entire substrate.

In this regard, a copper seed layer is deposited using, e.g., physical vapor deposition (PVD) methods, and the seed layer is typically deposited on a barrier layer. A seed layer deposition may require a pre-clean step to remove contaminants. The pre-clean step could be a sputter etch using an argon plasma, typically performed in a process chamber separate from the PVD chamber used to deposit the seed layer.

Electroless plating techniques can also be used to fill the charge transport material 24. The reaction is preferably driven by a redox reaction in the bath allowing plating on isolated features. The reaction is naturally selective and will only plate copper on itself or an activated surface such as TiO₂.

A typical electroless metal plating solution comprises a soluble ion of the metal to be deposited, a reducing agent and such other ligands, salts and additives that are required to obtain a stable bath having the desired plating rate, deposit morphology and other characteristics. Common reductants include hypophosphite ion, formaldehyde, hydrazine or dimethylamine-borane. The reductant reacts irreversibly at the catalyst core to produce an active hydrogen species. The choice of electroless metal plating solution is determined by the desired properties of the deposit, such as conductivity, magnetic properties, ductility, grain size and structure and corrosion resistance.

If the charge transport material 24 is heated to a temperature where copper has significant surface mobility, pores may be filled by diffusion of the copper atoms. This reflow process can be done in situ. If the feature is lined with a thin copper layer such as from CVD, sputtering more copper on the feature at temperatures of 300° to 400° C. can lead to filled pores. High aspect ratio holes can be filled in this manner.

Copper CVD can also be used for filling of the pores of the charge transport layer 10 using metallo-organic precursors. In this manner, Cu (HFAC) TMVS [copper(I) hexafluoroacetylacetonate vinyltrimethyl silane] is the main precursor used and is commercially available from Schumacher in a proprietary blend. The reaction requires 2 Cu (HFAC) TMVS molecules. One of the copper atoms is converted to Cu(II) (HFAC)₂, while the other is deposited as copper. The film is quite conformal even at high aspect ratios. Selective methods of deposition are possible where the reaction only takes place on active sites, such as an exposed metal pad. This process allows “bottom up” filling of very high aspect ratio pores.

After filling of the pores of the charge transport material 24, the resultant inter-digitated structure is oxidized by heat treatment to create a heterostructure between the charge transport material 24 and the optical absorbing material 26.

With specific reference to FIG. 5, the copper in the pores of the charge transport material 24 is oxidized to CuO or Cu₂O by heat treatment at 200-700° C. for a time ranging from several minutes to several hours depending upon the desired process conditions. For example, the charge transport material 24 is oxidized to CuO by heat treatment at about at 500° C. for five minutes on a hot plate. Alternatively, the copper is oxidized to Cu₂O by heat treatment at about 300° C. on a hot plate for about five minutes. As understood by one of skill in the art, different oxidation times, oxidation environments and oxidation may be used.

In addition, cuprous and cupric oxides can be directly electrodeposited from solutions of Cu(I) and Cu(II) salts. For example, CuO can be formed electrochemically from high pH (>10) copper sulfate electrolytic solutions stabilized by chelating agents such as tartaric acid. CuO is deposited directly on the anode of an electrochemical cell using such an electrolyte. Similar methods for Cu₂O are known to those of ordinary skill in the art.

In the event the pores of the charge transport material 24 are filled with an optical absorbing material 26 that is not an oxide of a metal (e.g., a sulfide or a phosphide of a metal as set out in Table I), the metal is initially deposited in the pores, preferably by electroplating. High aspect ratio filling is accomplished as is well-known to those of skill in the art using additives to the electroplating bath such as accelerants and surfactants to enhance growth at the bottom and suppress it near the top. As is well understood in the art, the electroplating processing conditions may vary depending upon the metal to be deposited. However, such electroplating process conditions are well-known for depositing the metals of the optical absorbing materials 26 of the present disclosures.

Once the pores of the charge transport material 24 are wholly or partially filled with the applicable metal, the device is sulfidized or phosphidized to convert the metal to a metal sulfide or metal phosphide.

For example, one known method for sulfidization involves exposing the structure to a plasma containing sulfur in the form of hydrogen sulfide or pure sulfur. H₂S is a gas at room temperature and can be used to generate a plasma forming tungsten sulfide. H₂S is problematic due to its toxicity.

In place of H₂S, a pure sulfur plasma could be used. The sulfur plasma is generated by introducing a charge of sulfur along with the sample into a small hot wall reactor such as a tube furnace or heated bell jar with appropriate electrodes. The unit is heated to generate a sulfur vapor pressure of 1 to 1000 mT. RF energy is supplied to the electrode at sufficient power as known by one of ordinary skill in the art.

Hydrogen, argon or other plasma enhancing agents may be added to the gas to ignite and sustain the sulfur plasma or speed the surface reactions. The advantages of plasma reaction is that highly energetic sulfur atoms and molecules can be generated without the need for a higher temperature. The energy of the sulfur atoms is sufficient to convert a layer of surface material to a metal sulfide without any detrimental effect on the film away form the surface. Plasma power or substrate temperature can be varied to control the thickness of the sulfidized layer as is well understood by one of ordinary skill in the art.

Using such a sulfidization process, the metal converts to a sulfide faster than the conversion of the metal oxide compound to a sulfide. For example, with reference to WO₃ and SnS as the charge transport material 24 and optical absorbing material 26, respectively, the Sn converts to SnS more rapidly than the conversion of WO₃ to WS₂.

In the event the metal used in the photovoltaic device 20 is to be phosphidized, the resultant interdigitated nanostructure is exposed to a plasma of phosphorous. The process and processing conditions would be like those described in connection with the sulfur plasma as understood by one of ordinary skill in the art.

Of course, in addition to plasma activation, there are other known processes for conversion of a metal to a phosphide or sulfide of the metal. For example, a thermal reaction using a gas containing S or P (e.g., H₂S) could also be used. UV radiation to activate the gaseous species is also a suitable alternative. These processes and their processing conditions are well understood by one of ordinary skill in the art. Still other processes are well-known to those of ordinary skill in the art for conversion of a metal to a phosphide or sulfide of the metal, and the present disclosure is intended to encompass all such processes.

Electrode 28 is deposited on the photovoltaic device 20 as indicated in FIG. 5. Examples of electrode 28 include platinum, gold, silver, graphite and aluminum. Electrode 28 is deposited using well-known processes, including a vacuum evaporation method, a sputtering method or a CVD (Chemical Vapor Deposition) method.

The disclosure is illustrated by examples without being limited thereby.

### EXAMPLE 1

A layer of ITO was sputter deposited on a glass substrate in a manner known by one of ordinary skill in the art. A layer of tungsten of approximately 40 nm in thickness was sputter deposited on the ITO. A 40 nm layer of copper was then sputter deposited on the tungsten layer without breaking vacuum. Vacuum was then broken. The W—Cu metal stack was heated on a hot plate at 500° C. for 15 minutes to create a WO₃/CuO heterojunction.

The resultant photovoltaic device exhibited an open circuit photovoltage of approximately 0.3 volts and a closed circuit current of approximately 1.8 mA/cm².

Including the substrate, the photovoltaic cell 10, 20 in FIGS. 1 and 5 generally has a thickness of from about 0.5 mm to about 2.0 mm.

To avoid reflection losses, the bottom side of the photovoltaic cell 10, 20, in FIGS. 1 and 5 can be provided with an antireflection coating having one, two, or more layers.

To increase the light yield, the reverse side of the photovoltaic cell 10, 20 in FIGS. 1 and 5 can be constructed in such a way that light is reflected back into the cell.

Another embodiment would be to use concentrated sunlight to improve the solar cell efficiency, for example, by using mirrors or Fresnel lenses.

The cells of the exemplary embodiments can also be part of a tandem cell; in such devices a plurality of subcells convert light from different spectral regions into electrical energy.

While particular embodiments have been described, alternatives, modifications, improvements, equivalents, and substantial equivalents that are or may be presently unforeseen may arise to applicants or others skilled in the art. Accordingly, the appended claims as filed and as they may be amended are intended to embrace all such alternatives, modifications, variations, improvements and substantial equivalents.

1. A solar photovoltaic device which comprises:
a heterostructure of a charge transport material and an optical absorbing material, the charge transport material and the optical absorbing material being binary compounds of two immiscible metals, the optical absorbing material having a bandgap of about 1.0 eV to about 1.8 eV;
a first transparent electrode disposed on a top surface of the heterostructure; and
a second electrode disposed on a bottom surface of the heterostructure.

2. The solar photovoltaic device of claim 1, wherein the charge transport material is tungsten oxide and the optical absorbing material is copper oxide.

3. The solar photovoltaic device of claim 1, wherein the device is planar.

4. The solar photovoltaic device of claim 1, wherein the device is an interdigitated heterostructure nanostructure of the charge transport material and the optical absorbing material.

5. The solar photovoltaic device of claim 1, wherein one or both of the charge transport material and optical absorbing material is doped to have a conduction band edge offset of greater than about 0.4 eV.

6. A semiconductor layer for a solar photovoltaic device which comprises:
a heterojunction of a charge transport material and an optical absorbing material, each of the charge transport material and the optical absorbing material being a different binary compound of two immiscible metals.

7. The semiconductor layer of claim 6, wherein the charge transport material is tungsten oxide and the optical absorbing material is copper oxide.

8. The semiconductor layer of claim 6, wherein the optical absorbing material has a bandgap of about 1.0 eV to about 1.8 eV.

9. The semiconductor layer of claim 6, wherein one or both of the charge transport material and optical absorbing material is doped to have a conduction band edge offset of greater than about 0.4 eV.

10. A method for making a heterojunction of inorganic semiconductors for a solar photovoltaic device comprising:
depositing a layer of a first metal;
depositing a layer of a second metal, the first metal and the second metal being immiscible metals;
forming a compound of the first metal in a depth of the first metal layer;
forming a compound of the second metal in a depth of the second metal layer so as to create a heterojunction between the compound of the first metal and the compound of the second metal.

11. The method of claim 10, wherein the compound of the first metal is tungsten oxide and the compound of the second metal is copper oxide.

12. The method of claim 10, wherein the compound of the second metal has a bandgap of about 1.0 eV to about 1.8 eV.

13. The method of claim 10, wherein the step of forming the compound of the first metal is carried out by oxidizing the first metal.

14. The method of claim 10, wherein the step of forming the compound of the second metal is carried out by oxidizing the second metal.

15. The method of claim 10, including the step of doping one or both of the compound of the first metal and the compound of the second metal to create a conduction band edge offset of greater than about 0.4 eV between the compound of the first metal and the compound of the second metal.

16. A method for making a solar photovoltaic device comprising:
depositing a layer of a compound of a first metal on a first electrode;
depositing a layer of a compound of a second metal on the layer of the compound of the first metal, the first metal and the second metal being immiscible metals, so as to create a heterostructure of the compound of the first metal and the compound of the second metal; and
forming a second electrode on the heterostructure of the compound of the first metal and the compound of the second metal.

17. The method of claim 16, wherein the compound of the first metal is tungsten oxide and the compound of the second metal is copper oxide.

18. The method of claim 16, wherein the compound of the second metal has a bandgap of about 1.0 eV to about 1.8 eV.

19. The method of claim 16 including the step of doping one or both of the compound of the first metal and the compound of the second metal to create a conduction band edge offset of greater than about 0.4 eV between the compound of the first metal and the compound of the second metal.

20. The method of claim 16, wherein the step of depositing the compound of the first metal is carried out by thermal evaporation.

21. The method of claim 16, wherein the step of depositing the compound of the second metal is carried out by thermal evaporation.

22. The method of claim 16, wherein the first electrode is transparent.
